(19) United States
(12) Patent Application Publication
(10) Pub. No.: US 2026/0051345 A1
(43) Pub. Date: Feb. 19, 2026

(54) TORQUE-BASED MAGNETORESISTIVE MEMORY WITH IMPROVED READ PERFORMANCE

(71) Applicant: COMMISSARIAT À L'ENERGIE ATOMIQUE ET AUX ENERGIES ALTERNATIVES, PARIS (FR)

(72) Inventors: Bernard VIALA, GRENOBLE (FR); Denys LY, GRENOBLE (FR)

(21) Appl. No.: 19/291,775

(22) Filed: Aug. 6, 2025

(30) Foreign Application Priority Data
Aug. 13, 2024 (FR) 2408896

(51) Int. Cl. G11C 11/16; H10N 50/10; H10N 50/80

(52) U.S. Cl. CPC G11C 11/1659; G11C 11/161; G11C 11/1673; G11C 11/1675; H10N 50/10; H10N 50/80

(57) ABSTRACT

A memory circuit includes a read circuit and a memory array (M1, M2) including at least one magnetoresistive memory cell, the memory cell including: a pillar; a write track made of a material exhibiting the spin Hall effect or a material exhibiting the orbital Hall effect; a first selector and a second selector, each selector being configured to switch from an off state to an on state when the amplitude of the voltage across the terminals of the selector is higher than a predetermined threshold voltage Vₜₕ; the read circuit including: a current source configured to inject a read current (I_{read}) through the first selector; a detect circuit configured to detect when the second selector switches from an off state to an on state in response to injection of the read current (I_{read}) by detecting the resistive state of the magnetic tunnel junction.

### CROSS-REFERENCE TO RELATED APPLICATION

This application claims priority to foreign French patent application No. FR 2408896, filed on Aug. 13, 2024, the disclosure of which is incorporated by reference in its entirety.

### FIELD OF THE INVENTION

The present invention relates to the field of design of non-volatile memory circuits and more particularly to improvement of the read performance of magnetoresistive memory cells based on spin-orbit torque or the orbital Hall effect.

### Technical problem

SOT-MRAM (SOT standing for Spin-Orbit Torque and MRAM standing for Magnetoresistive Random-Access Memory) is an advanced non-volatile memory that uses magnetic mechanisms to store data. It is based on a pillar-shaped magnetic tunnel junction the resistance of which varies as a function of the orientation of the magnetic layers. Unlike conventional MRAM, SOT-MRAM makes use of spin-orbit torque, whereby currents flowing through a track formed by materials exhibiting strong spin-orbit coupling induce switching of the magnetic state in a tunnel junction structure making contact with said track. This allows faster switching, better endurance and increased energy efficiency to be achieved. SOT-MRAM is ideal for applications requiring fast, non-volatile and durable memory. This durability is obtained by virtue of the fact that writing does not require the write current to pass through the pillar-shaped magnetic tunnel junction.

Two states are defined for a non-volatile memory: a low resistive state (LRS) and a high resistive state (HRS). To carry out a read operation, the current through the pillar-shaped magnetic tunnel junction is measured by applying a read voltage V_{read} across the terminals of said junction. When the junction is in a high resistive state, a current I_{read-HRS} is measured corresponding to a resistance denoted R_{AP} (Anti-Parallel configuration) in the case of an MRAM memory cell. When it is in a low resistive state, a current I_{read LRS} higher than I_{read-HRS} is measured corresponding to a resistance denoted R_{P} (Parallel configuration) in the case of an MRAM memory cell. For a non-volatile memory, a first criterion higher than 1 denoted “read margin” MW is defined that depends on the ratio I_{read-LRS}/I_{read-HRS}. The “read disturb margin” (RDM) depends on the stability of this ratio. This means that I_{read-LRS} and I_{read-HRS} must remain significantly different and as stable as possible over time, even after many write and read cycles. Drift in the read currents I_{read-LRS} and I_{read-HRS} may be caused by heating in the materials from which the pillar-shaped magnetic tunnel junction is made, induced by the read currents. Repeated heating induces a loss of the stability of the spins in the magnetic tunnel junction and thus a drift in the values of I_{read-LRS} and I_{read HRS} and thus an increase in the risk of read disturbance.

In addition, in SOT-MRAMs, the difference between the high and low resistive states is very small compared to what it is in other memory technologies. This drawback limits the dynamic range (also called memory window) of the constituent memory cells of the data storage circuit. The limitation of the dynamic range of the memory cells considerably decreases the ability of read circuits to differentiate between the levels of resistance and increases read disturbance.

Thus, there is a need to design new MRAM memory-cell architectures in which the read margin MW remains stable, the read disturb margin RDM is decreased and the difference between the currents I_{read-LRS} and I_{read-HRS} is increased. These three criteria allow the reliability with which a memory circuit based on MRAM memory cells may be read to be considerably increased.

The same need exists with the OTT-MRAM memory concept (OTT standing for Orbital Transfer Torque) which uses the injection of currents of orbital torques instead of spin currents by replacing the tungsten SOT write track with an OTT track that may for example be made of titanium. The invention is described for SOT-MRAM memory cells with a write track made of a material exhibiting the spin-orbit-torque effect but also remains valid for OTT-MRAM memories. The advantages and features described in the context of SOT-MRAM memory cells remain valid for OTT-MRAM memories.

### Answer to the Problem and Solution Provided

To overcome the limitations of the existing solutions, the invention provides a memory circuit based on SOT-MRAM memory cells with two selectors, and a plurality of embodiments of corresponding read circuits. Read-out with the read circuit according to the invention is based on injection of a read current and not on a read voltage. A low resistive state is read by reading a leakage current and not an injected read current. This allows the difference between I_{read-LRS} and I_{read HRS} to be increased and therefore the reliability of the read circuit according to the invention to be improved. In addition, the read circuit according to the invention allows the current flowing through the magnetic tunnel junction (MTJ) during read-out of a high resistive state (HRS) to be minimized. This allows the effects of heating in the tunnel junction to be decreased and thus the read margin MW of the memory to be stabilized for a plurality of read/write cycles.

In addition, the invention provides a plurality of memory-array architectures that are based on SOT-MRAM memory cells and that are compatible with the various read modes for which the invention makes provision.

### SUMMARY OF THE INVENTION

The subject of the invention is a memory circuit comprising a read circuit and a memory array comprising at least one magnetoresistive memory cell, the memory cell comprising:
a pillar forming a magnetic tunnel junction having an upper end and a lower end, said upper end forming a first node intended to receive a first control voltage;
a write track made of a material exhibiting the spin Hall effect or a material exhibiting the orbital Hall effect, the pillar being placed, on said write track, on the side of its lower end with a view to configuring the resistance of the magnetic tunnel junction between a high resistive state R_{AP} and a low resistive state R_{P};
a second node intended to receive a second control voltage and a third node;
a first selector mounted between the third node and a first end of the write track and a second selector mounted between the second node and a second end of the write track opposite the first end.
   Each selector is configured to switch from an off state to an on state when the amplitude of the voltage across the terminals of said selector is higher than a predetermined threshold voltage Vₜₕ. The read circuit comprises:
a current source connected to the third node and configured to inject a read current through the first selector;
a detect circuit configured to detect when the second selector switches from an off state to an on state in response to injection of the read current by detecting the resistive state of the magnetic tunnel junction.

According to one particular aspect of the invention, the detect circuit comprises a current comparator having a first input connected to the second node and having a second input receiving a reference current lower than the read current and higher than the leakage current of the second selector when it is in an off state.

According to one particular aspect of the invention, the detect circuit comprises a current comparator having a first input connected to the first node and having a second input receiving a reference current lower than the read current and higher than the leakage current of the magnetic tunnel junction when it is in a high resistive state R_{AP}.

According to one particular aspect of the invention, the detect circuit comprises a current comparator having a first input connected to the first node and having a second input connected to the second node.

According to one particular aspect of the invention, the current source is configured to inject a read current having an amplitude higher than

$$\frac{{R}_{AP} + {R}_{OFF , S 2}}{{R}_{AP} {R}_{OFF , S 2}} {V}_{th}$$

and lower than

$$\frac{{R}_{P} + {R}_{OFF , S 2}}{{R}_{P} {R}_{OFF , S 2}} {V}_{th} ,$$

R_{OFF,S2} being the resistance of the second selector when it is in the off state.

According to one particular aspect of the invention, the current source is configured to inject a read current having an amplitude higher than

$$\frac{{V}_{th}}{{R}_{OFF , S 1}} ,$$

R_{OFF,S1} being the resistance of the first selector when it is in the off state.

According to one particular aspect of the invention, the current source is configured to inject a read current having an amplitude higher than

$$\frac{{V}_{th}}{{R}_{OFF , S 1}}$$

then to increase the amplitude of the read current until a value higher than

$$\frac{{R}_{P} + {R}_{OFF , S 2}}{{R}_{P} {R}_{OFF , S 2}}$$

Vₜₕ is reached, R_{OFF,S1} being the resistance of the first selector when it is in the off state, R_{OFF,S2} being the resistance of the second selector when it is in the off state.

According to one particular aspect of the invention:
the first nodes of the memory cells belonging to the same column of the memory array are interconnected via a first conductive line intended to propagate the associated first control voltage;
the second nodes of the memory cells belonging to the same row of the memory array are interconnected via a second conductive line intended to propagate the associated second control voltage;
the third nodes of the memory cells belonging to the same row of the memory array are interconnected via a third conductive line intended to propagate the read current.

According to one particular aspect of the invention, the memory circuit further comprises control means configured to read a selected memory cell of the array by connecting its first node and its second node to electrical ground, and by applying, to non-selected memory cells, a first non-zero control voltage lower than the predetermined threshold voltage Vₜₕ.

According to one particular aspect of the invention:
the first nodes of the memory cells belonging to the same column of the memory array are interconnected via a first conductive line intended to propagate the associated first control voltage;
the second nodes of the memory cells belonging to the same column of the memory array are interconnected via a second conductive line intended to propagate the associated second control voltage;
the third nodes of the memory cells belonging to the same row of the memory array are interconnected via a third conductive line intended to propagate the read current.

According to one particular aspect of the invention, the memory circuit further comprises control means configured to read a selected memory cell of the array by connecting its first node and its second node to electrical ground, and by applying, to non-selected memory cells, a first non-zero control voltage lower than the predetermined threshold voltage Vₜₕ and a second non-zero control voltage lower than the predetermined threshold voltage Vₜₕ.

### BRIEF DESCRIPTION OF THE DRAWINGS

Other features and advantages of the present invention will become more clearly apparent on reading the following description with reference to the following appended drawings.

FIG. 1 illustrates a cross-sectional view of an SOT-MRAM memory cell used in the memory circuit according to the invention.

FIG. 2 illustrates a functional diagram of the memory circuit according to the invention.

FIG. 3 illustrates a functional diagram of a read circuit according to a first embodiment of the invention, associated with an SOT-MRAM memory cell.

FIG. 4a illustrates the read circuit according to the first embodiment of the invention during read-out of an LRS.

FIG. 4b illustrates a timing diagram of the currents and voltages of an SOT-MRAM memory cell during read-out of an LRS by the read circuit according to the first embodiment of the invention.

FIG. 5a illustrates the read circuit according to the first embodiment of the invention during read-out of an HRS.

FIG. 5b illustrates a timing diagram of the currents and voltages of an SOT-MRAM memory cell during read-out of an HRS by the read circuit according to the first embodiment of the invention.

FIG. 6a illustrates a functional diagram of a read circuit according to a second embodiment of the invention, associated with an SOT-MRAM memory cell.

FIG. 6b illustrates a functional diagram of a read circuit according to a third embodiment of the invention, associated with an SOT-MRAM memory cell.

FIG. 7a illustrates an electrical schematic of a first memory array used in the memory circuit according to the invention.

FIG. 7b illustrates an electrical schematic of a second memory array used in the memory circuit according to the invention.

### DETAILED DESCRIPTION

The invention relates to a memory circuit comprising an array formed from SOT-MRAM memory cells. By way of non-limiting indication, to start with one example of an SOT-MRAM memory cell allowing a memory circuit according to the invention to be formed will be described.

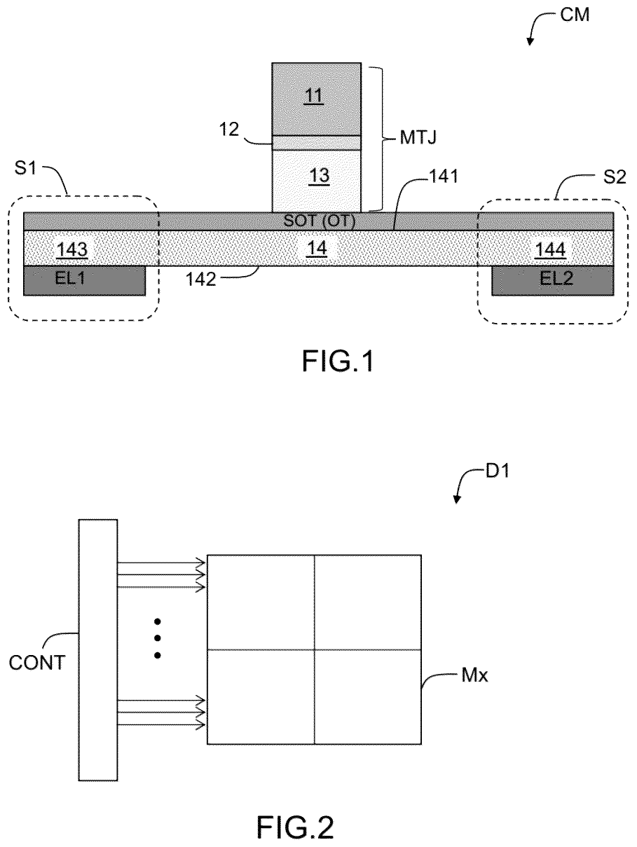

FIG. 1 illustrates a cross-sectional view of an SOT-MRAM memory cell CM used in the memory circuit according to the invention. The memory cell CM comprises a magnetic tunnel junction MTJ, a write track SOT, a carrier layer 14, a first electrode EL1 and a second electrode EL2.

The magnetic tunnel junction MTJ is a magnetoresistive pillar comprising a stack of layers 11, 12, 13 that work together to allow data to be stored and read via manipulation of magnetic properties. The stack comprises a first ferromagnetic reference layer 11 in which the direction of the magnetic polarization is set and uniform. The stack further comprises a second ferromagnetic layer 13 in which the direction of the magnetic polarization is variable. The stack further comprises a tunnel barrier layer 12 of an oxide, such as MgO (magnesium oxide), confined between the first and second ferromagnetic layers 11, 13. This layer plays a crucial role in the magnetoresistive tunnelling effect, allowing electrons to pass through via quantum tunnelling. The first ferromagnetic layer 11 serves as a reference for detecting changes in magnetization in the free ferromagnetic layer 13. For example, the first and second layers 11, 13 are made of materials such as CoFeB. The operating principle of the magnetoresistive pillar MTJ is based on the change in electrical resistance as a function of the orientation of the magnetic polarization of the free ferromagnetic layer 13 with respect to the orientation of the magnetic polarization in the reference ferromagnetic layer 11. When the magnetizations of the free and reference layers 11, 13 are parallel, electrical resistance is low through the magnetic tunnel junction MTJ. When the magnetizations are antiparallel, electrical resistance is high. This change in resistance is detected to read a state of the memory (bit 0 or 1). This change in resistance is caused to write a state of the memory (bit 0 or 1).

The magnetic tunnel junction MTJ is placed on the write track SOT. The interface between the magnetic tunnel junction MTJ and the write track SOT is on the side of the free ferromagnetic layer 13. The direction of the stack forming the magnetic tunnel junction MTJ is orthogonal to the plane formed by the layer forming the write track SOT. The write track SOT is made of a material exhibiting the spin Hall effect (which material could also be referred to as a material generating a spin-orbit torque), for example beta-phase tungsten or bismuth antimonide or a BiSbTe alloy or a stack of two layers, one of tantalum and the other of tungsten. When a write current passes through the write track SOT in one direction, spin currents are generated and interact with the free ferromagnetic layer 13. This interaction allows the direction of the write current in the write track SOT to be used to control the direction of the magnetic polarization in the free ferromagnetic layer 13. Controlling the direction of the magnetic polarization in the free ferromagnetic layer 13 allows the electrical resistance of the magnetic tunnel junction MTJ to be modified without injecting a write current into it, this considerably increasing the robustness of the memory cell CM.

The write track SOT is placed on a first face 141 of the carrier layer 14. The carrier layer 14 is made of a material exhibiting a metal-insulator transition, and more particularly of a Mott oxide. This type of material is able to make volatile resistive transition between a high resistive state and a low resistive state. This transition is thermally and/or electrically and/or optically activated. It consists of a non-permanent (volatile) phase change between a stable, high-resistance semiconductor ortho-clinical phase and a metastable, low-resistance, conductive rutile tetragonal phase. The low resistive state is maintained only under thermal, electrical or optical stimulation. The invention employs electrical stimulation obtained by applying an electric field.

The first electrode EL1 is placed on a second face 142 of the carrier layer 14 opposite the first face 141. The first electrode EL1 is positioned below a first end of the write track SOT. The second electrode EL2 is placed on the second face 142. The second electrode EL2 is positioned below a second end of the write track SOT opposite the first end. The pillar forming the magnetic tunnel junction MTJ is located between the first end and the second end. The first electrode EL1 and the second electrode EL2 are each formed by an electrically conductive layer made of metal, for example preferably tungsten or copper or titanium nitride.

From an electrical point of view, a first control voltage VRBL is applied to the upper end of the pillar forming the magnetic tunnel junction MTJ, which forms a first input/output node RBL. A second control voltage VBLB is applied to the second electrode EL2, which forms a second input/output node BLB. A third control voltage VBL is applied to the first electrode EL1, which forms a third input/output node BL.

The stack formed by the first electrode EL1, zone 143 of the carrier layer 14 made of a material exhibiting a metal-insulator transition and the write track SOT locally forms a selector S1 of small size. The selector S1 is configurable between a high resistive state R_{OFF,1} and a low resistive state R_{ON,S1} via application of a voltage between the first electrode EL1 and the write track SOT, i.e. the first and third voltages VRBL, VBL. Likewise, the stack formed by the second electrode EL2, zone 144 of the carrier layer 14 made of a material exhibiting a metal-insulator transition and the write track SOT locally forms a second selector S2 of small size. The second selector S2 is configurable between a high resistive state R_{OFF.S2} and a low resistive state R_{ON,S2} via application of a voltage between the second electrode EL2 and the write track SOT, i.e. the first and second voltages VRBL, VBLB. For each selector among S1 and S2, activation (passage from R_{OFF} to R_{ON}) is triggered when the amplitude of the voltage across the terminals of the selector exceeds a predetermined threshold voltage Vₜₕ. For example, for a carrier layer 14 made of vanadium oxide, the threshold voltage is equal to 0.6 V, this being compatible with the voltage operating ranges of a magnetoresistive memory cell.

Alternatively, the carrier layer 14 comprises a material that behaves as a topological insulator at low voltages (<1 V), molybdenum disulfide for example. A topological insulator is a material that has the advantageous property of behaving as an insulator in its interior (it does not conduct electricity through its bulk), while having conductive surfaces or edges. This type of material is said to be “topological” because its conductive surface properties are protected by topological characteristics of the electronic structure of the material, this meaning that they are robust against faults such as impurities or structural defects.

The selectors S1, S2 may be activated simultaneously by means of the same control voltage (same amplitude and same sign) or independently by means of two separate control voltages (same amplitude and opposite signs). Depending on the sign of the applied voltage, it is therefore possible to manage the ‘on’ direction of the selectors-either upwards (from the associated electrode to the write track SOT) or downwards (from the write track SOT to the electrode). Thus, a bipolar current may flow through the entire track SOT in the write case when the commands are of opposite signs, and a unipolar current may flow through the pillar MTJ after having passed through half of the track SOT in the read case when the commands are of same sign.

In the embodiment of FIG. 1, the direction of the stack is as follows starting from the substrate and proceeding along the Z axis: the electrodes EL1; EL2 then the carrier layer 14 then the write track SOT then the pillar MTJ. Alternatively, the memory cell 10 may be formed in the inverse direction to the cell illustrated in FIG. 1, starting from the substrate as origin of the Z axis. The pillar is then directed downwards. The direction of the stack is then as follows starting from the substrate and proceeding along the Z axis: the downwardly directed pillar MTJ, then the write track SOT, then the carrier layer 14 and then the electrodes EL1, EL2 on the upper surface. The downwardly directed pillar MTJ is encapsulated in a dielectric layer.

Alternatively, the memory cell 10 according to the invention is a magnetoresistive memory cell exploiting the orbital Hall effect. This embodiment differs from the embodiment in FIG. 1 in that the write track is configured to generate a current of orbital moments from a current of charges and not a current of spins. The advantage of having a write path separate from the read path is retained. Writing is achieved through conversion of the current of charges into a current of orbital moments that has an ability similar to the current of spins to exert a torque on the magnetization of a magnetic layer. This is the orbital Hall effect (abbreviated OHE), which differs from the spin Hall effect. Writing using the orbital Hall effect allows the characteristics of magnetic memories to be improved. The structure of a device employing the orbital Hall effect is similar to the structure of an SOT device, the difference being that the write track (then referenced OT for “Orbital Torque”) is a track configured to generate a current of orbital moments from a current of charges. The orbital moments do not allow a torque to be applied directly to the magnetization of the junction of the pillar MTJ. One of the following two mechanisms may be required. The action of the orbital moments on the magnetization may be due to a spin-orbital entanglement and/or part of the current of orbital moments may be converted into a current of spins for the junction of the pillar MTJ, said spins applying a torque to a magnetization of the junction of the pillar MTJ. In the case of a memory cell employing the orbital Hall effect, the write track SOT is made of chromium or zirconium or titanium or vanadium or copper or manganese or molybdenum or ruthenium or aluminium or niobium or alpha-phase tungsten.

FIG. 2 illustrates a functional diagram of a memory circuit D1 according to the invention, comprising a memory array Mx formed by a plurality of memory cells CM according to the invention, a control circuit CONT and at least one read circuit CL. The control circuit CONT is configured to generate the first control voltage VRBL, the second control voltage VBLB and the third control voltage VBL for each memory cell CM. The read circuit CL is configured to read the logic state stored in a memory cell CM of the array Mx.

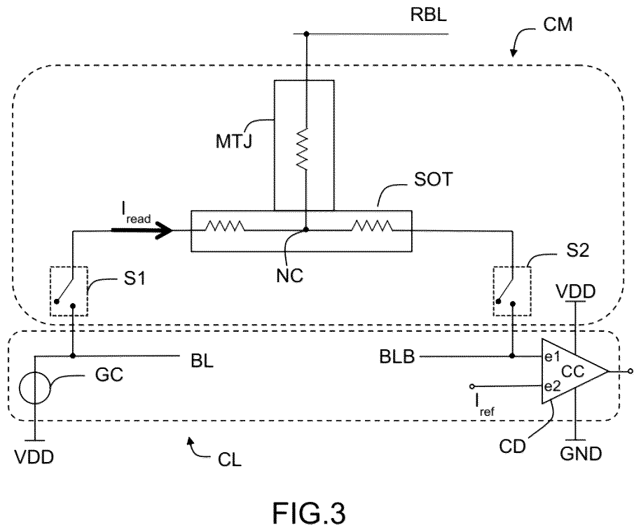

FIG. 3 illustrates a functional diagram of a read circuit CL according to a first embodiment of the invention. The read circuit CL is associated with an SOT-MRAM memory cell CM to illustrate how a read operation works according to the invention.

In the memory cell CM, the first selector S1 behaves as a switch controlled by the potential difference VS1. When the first selector S1 is in an on state, it may be likened to a resistor of resistance R_{ON,S1} and when it is in an off state, to a resistor of resistance R_{OFF,S1}. The second selector S2 behaves as a switch controlled by the potential difference VS2. When the second selector S2 is in an on state, it may be likened to a resistor of resistance R_{ON,S2} and when it is in an off state, to a resistor of resistance R_{OFF,S2}. The segment of the write track SOT located between the first selector S1 and the base of the pillar MTJ is modelled by a resistor of resistance R_{SOT}/2 with R_{SOT} being the equivalent electrical resistance of the write track. Symmetrically, the segment of the write track SOT located between the second selector S2 and the base of the pillar MTJ is modelled by a resistor of resistance R_{SOT}/2. The two resistors of resistance R_{SOT}/2 are connected in series, and their common node NC is a central node located at the base of the pillar MTJ. The pillar MTJ is modelled by a resistor the resistance R_{MTJ} of which varies depending on the binary datum “1” or “0” stored in the memory cell CM. To simplify the description of the invention, it is assumed that the two selectors S1 and S2 are identical and therefore that R_{OFF,S1}=R2_{OFF,S2} and that R_{ON,S1}=R_{ON,S2}.

The read circuit CL comprises a current source GC connected to the third node BL and configured to inject a read current I_{read} through the first selector S1 so as to trigger a read operation. The direction of the read current I_{read} is from the third node BL to the write track SOT. The amplitude of the read current I_{read} is higher than Vth/R_{OFF,S1} in order to cause the first selector S1 to switch to a conducting state under the action of the read current I_{read}.

The read circuit CL further comprises a detect circuit CD configured to detect when the second selector S2 switches from an off state to an on state in response to injection of the read current I_{read}. According to one particular aspect of the invention, the detect circuit CD is a current comparator CC having a first input e1 connected to the second node BLB and a second input e2 receiving a reference current I_{ref}. The first input e1 receives the current _{Is2}, which flows through the second selector S2. If the second selector S2 is in the off state, a leakage current I_{S2}=I_{leak,s2} lower than 5 μA flows through it. If the second selector S2 is in the on state, a current almost equal to the read current I_{S2}≈I_{read} flows through it. By close to the read current I_{read}, what is meant is a current having an amplitude higher than 80% of the amplitude of the read current I_{read}. The current comparator CC is configured to generate a high logic state on its output when the current received on its first input is the leakage current I_{S2}=I_{leak,s2}. Conversely, the current comparator CC is configured to generate a low logic state on its output when the current received on its first input e1 is close to the read current I_{read} (or vice versa depending on the convention chosen). To allow this function to be performed, the reference current I_{ref} has an amplitude lower than the read current I_{read} and higher than the leakage current I_{leak,s2} of the second selector S2 when it is in an off state.

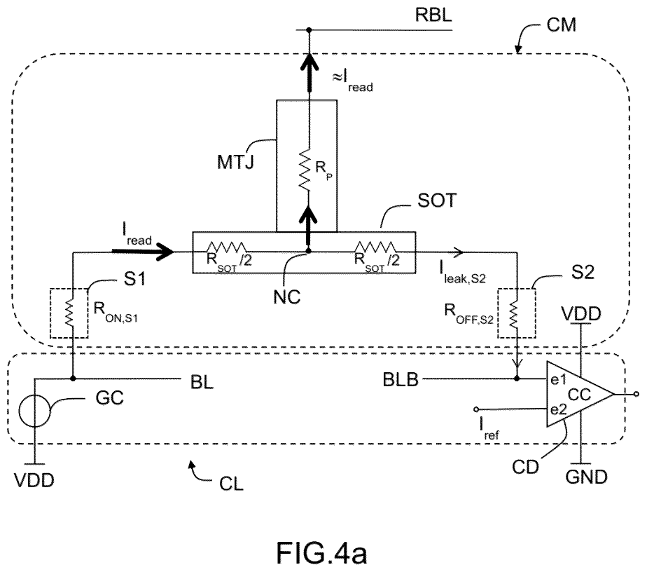

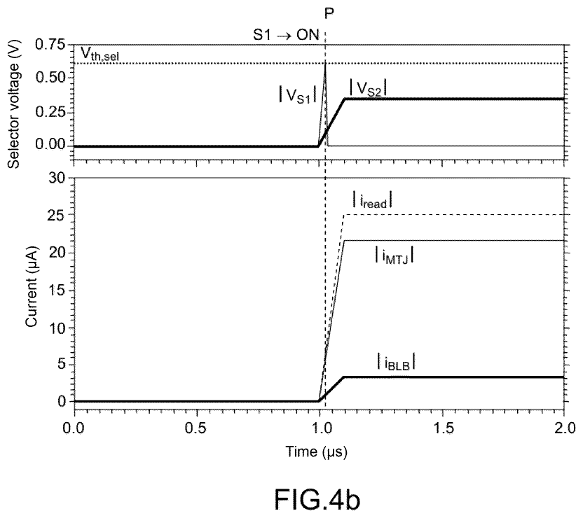

FIG. 4a illustrates operation of the read circuit CL according to the first embodiment of the invention during read-out of an LRS. It will be recalled that an LRS (abbreviation of low resistive state) corresponds to a parallel distribution of the spins in the pillar MTJ giving a low resistance R_{P}. Initially, the two selectors S1 and S2 are in an off state. The control circuit CONT is configured to apply a first control voltage VRBL=0 and a second control voltage VBLB=0. To trigger a read operation, the current source GC is configured to inject into the first selector S1 a read current I_{read} higher than

$$\frac{{V}_{th}}{{R}_{OFF , S 1}} ,$$

this inducing the first selector S1 to switch to an on state. At the central node NC, the read current is distributed between the branch corresponding to the pillar MTJ and the branch corresponding to the second selector S2 such that I_{read}=I_{S2}+I_{MTJ}. The pillar MTJ has the least resistive current path among the two branches because R_{P}<R_{OFF,S2}. The ratio

$$\frac{{I}_{MTJ}}{{I}_{S 2}}$$

depends on the ratio

$$\frac{{R}_{OFF , S 2}}{{R}_{MTJ}} :$$

when R_{MTJ}=R_{P} the ratio

$$\frac{{I}_{MTJ}}{{I}_{S 2}}$$

is high and when R_{MTJ}=R_{AP} the ratio

$$\frac{{I}_{MTJ}}{{I}_{S 2}}$$

is minimum. The amplitude of the read current I_{read} is lower than

$$\frac{{R}_{P} + {R}_{OFF , S 2}}{{R}_{P} {R}_{OFF , S 2}} {V}_{th}$$

so as to have, in this configuration, a current I_{S2} that allows the second selector S2 to be kept in an off state. To conclude, when the pillar MTJ is in the LRS, injection of the read current I_{read} according to the invention allows the first selector S1 to be switched to an on state but the second selector S2 to be kept in an off state. The second selector S2 thus passes its leakage current I_{S2}=I_{leak,s2} while the magnetic tunnel junction MTJ passes a current I_{MTJ}≈I_{read}. The current comparator CC receives, on its first input e1, a current lower than the reference current I_{ref} and generates a high logic state (or vice versa depending on the convention chosen) corresponding to the logic state stored in the memory cell CM.

FIG. 4b illustrates a timing diagram of the currents and voltage of a memory cell CM during read-out of an LRS by the read circuit according to the first embodiment of the invention. The read current I_{read} increases gradually until it reaches a value higher than

$$\frac{{V}_{th}}{{R}_{OFF , S 1}} ,$$

to switch the first selector S1 to an on state. The moment when the first selector switches corresponds to the pulse observed for the voltage VS1. Next, a steady state is reached in which the voltage VS2 has a constant value lower than Vₜₕ, this inducing the second selector S2 to remain in an off state. In this configuration, the current through the selector S2 stabilizes at a value lower than 5 μA (3.4 μA in the example illustrated) and the current through the pillar MTJ stabilizes at a value close to the read current I_{read}.

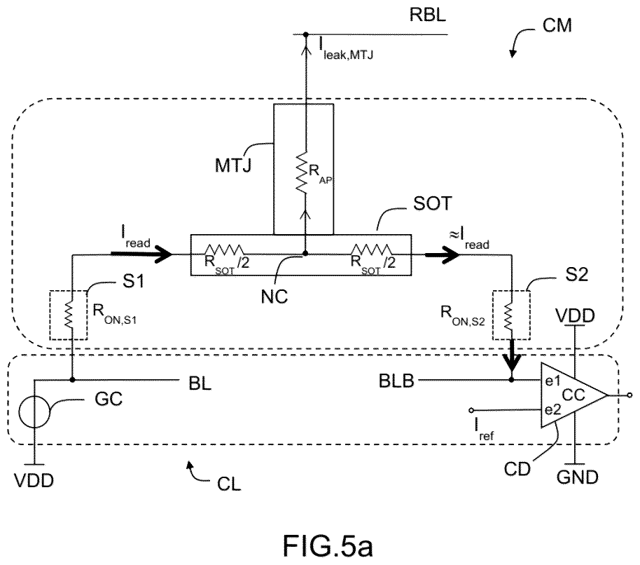

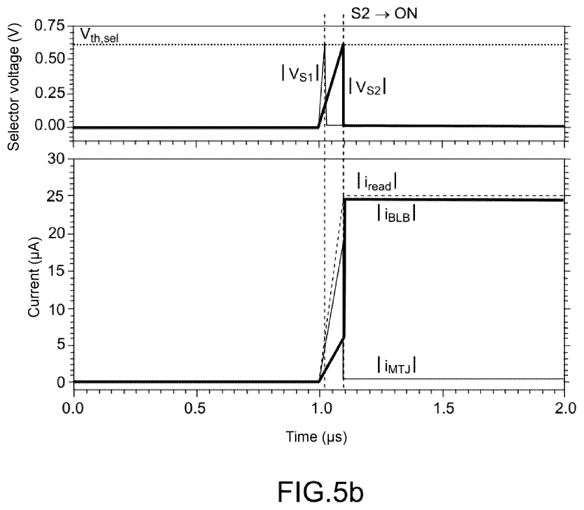

FIG. 5a illustrates operation of the read circuit CL according to the first embodiment of the invention during read-out of an HRS. It will be recalled that the HRS (abbreviation of high resistive state) corresponds to an anti-parallel distribution of the spins in the pillar MTJ giving a high resistance R_{AP}. Initially, the two selectors S1 and S2 are in an off state. The control circuit CONT is configured to apply a first control voltage VRBL=0 and a second control voltage VBLB=0. To trigger a read operation, the current source GC is configured to inject into the first selector S1 a read current I_{read} higher than

$$\frac{{V}_{th}}{{R}_{OFF , S 1}} ,$$

this inducing the first selector S1 to switch to an on state. At the central node NC, the read current is distributed between the branch corresponding to the pillar MTJ and the branch corresponding to the second selector S2 such that I_{read}=I_{S2}+I_{MTJ}. The amplitude of the read current I_{read} is higher than

$$\frac{{R}_{AP} + {R}_{OFF , S 2}}{{R}_{AP} {R}_{OF F , S 2}} {V}_{th}$$

so as to have, in this configuration, a current I_{S2} that allows the second selector S2 to be switched to an on state. Thus, a short circuit is created between the second node BLB and the third node BL, when the pillar MTJ is in the HRS. Injection of the read current I_{read} according to the invention allows the first selector S1 and the second selector S2 to be successively switched to an on state. The second selector S2 thus passes a current almost equal to the read current I_{S2}≈I_{read}, while the magnetic tunnel junction MTJ passes a leakage current I_{MTJ}=I_{leak,MTJ}. The current comparator CC receives on its first input e1 a current higher than the reference current I_{ref} and generates a low logic state “0” (or vice versa depending on the chosen convention) corresponding to the logic state stored in the memory cell CM.

FIG. 5b illustrates a timing diagram of the currents and voltage of a memory cell CM during read-out of an HRS by the read circuit CL according to the first embodiment of the invention. The read current I_{read} increases gradually until it reaches a value higher than

$$\frac{{V}_{th}}{{R}_{OFF , S 1}}$$

to switch the first selector S1 to an on state. The moment when the first selector switches corresponds to the pulse observed for the voltage VS1. In response thereto, the current I_{S2} through the second selector S2 gradually increases until it reaches a value higher than

$$\frac{{V}_{th}}{{R}_{OFF , S 2}}$$

to switch the second selector S2 to an on state. The moment when the second selector switches corresponds to the pulse observed for the voltage VS2. Next, a steady state is reached in which the current through the selector S2 stabilizes at a value almost equal to the amplitude of the read current I_{read}, and the current through the pillar MTJ stabilizes at a residual value corresponding to the leakage current through the pillar I_{leak,MTJ}.

A first advantage resulting from the read operation according to the invention is that the magnitude of the current allowing an LRS to be read, which corresponds to the leakage current of the selector S2, is minimized. Thus, the invention allows the dynamic range of the memory cell CM to be increased. This induces an improvement in the ability of the read circuit CL according to the invention to differentiate between the resistance levels and induces a considerable decrease in read disturbances.

One additional advantage is that the magnitude of the current flowing through the pillar MTJ during read-out of an HRS, which corresponds to the leakage current of the tunnel junction, is minimized. Thus, the invention allows the effects of heating in the tunnel junction to be decreased and therefore the read margin MW of the memory cell CM according to the invention to be stabilized.

Advantageously, the read current is injected sequentially in a succession of phases. Thus, the current source GC is configured to inject, in a first phase, a read current I_{read} having an amplitude higher than

$$\frac{{V}_{th}}{{R}_{OFF , S 1}} ,$$

to switch the first selector S1 first. Next, the current source GC is configured to increase the amplitude of the read current I_{read} until a value higher than

$$\frac{{R}_{AP} + {R}_{OFF , S 2}}{{R}_{AP} {R}_{OFF , S 2}} {V}_{th}$$

but lower than is

$$\frac{{R}_{P} + {R}_{OFF , S 2}}{{R}_{P} {R}_{OFF , S 2}} {V}_{th}$$

is reached, to potentially switch the second selector S2. This two-phase operation makes it possible to avoid the risk of breakdown of the memory cells following abrupt application of a current of high magnitude. Alternatively, the current source GC is configured to gradually step up the read current I_{read}.

Alternatively, the current source GC is configured to inject a read current I_{read} that increases upwards to its final value with a rise time that is sufficiently long to avoid breakdown of the memory cell. By sufficiently long time, what is meant is a rise time between the current value

$$\frac{{V}_{th}}{{R}_{OFF , S 1}}$$

(to switch the selector S1) and the final current value

$$( \geq \frac{{R}_{AP} + {R}_{OFF , S 2}}{{R}_{AP} {R}_{OFF , S 2}} {V}_{th} but < \frac{{R}_{P} + {R}_{OFF , S 2}}{{R}_{P} {R}_{OFF , S 2}} {V}_{th} )$$

longer than the switching time of the selectors, for example longer than or equal to 5 ns.

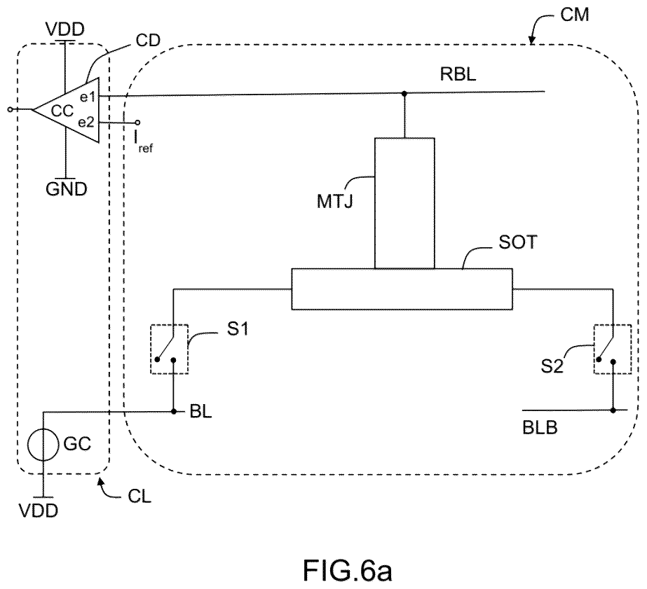

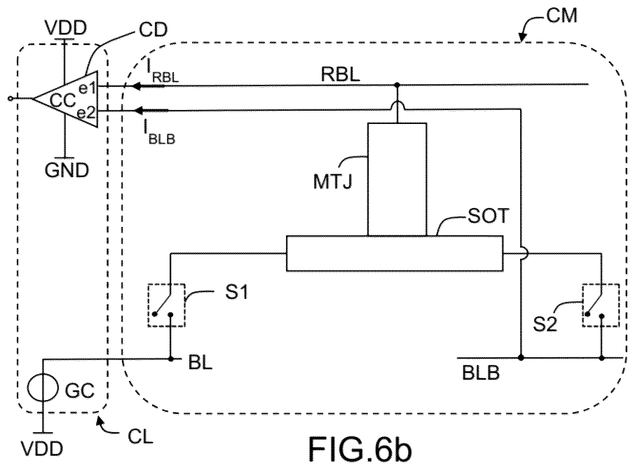

FIG. 6a illustrates a functional diagram of a read circuit CL according to a second embodiment of the invention, associated with a memory cell CM. The second embodiment differs from the first embodiment in the arrangement of the current comparator CC. In the second embodiment, the first input e1 of the current comparator CC is connected to the first input/output node RBL to compare the current flowing through the pillar tunnel junction MTJ with the reference current I_{ref}. In the second embodiment, the reference current I_{ref} has an amplitude lower than the read current I_{read} and higher than the leakage current I_{leak,MTJ} of the pillar MTJ when it is in an HRS. The operation and advantages described with respect to the first embodiment remain valid for the second embodiment.

FIG. 6b illustrates a functional diagram of a read circuit CL according to a third embodiment of the invention, associated with a memory cell CM. The third embodiment differs from the first embodiment in the arrangement of the current comparator CC. In the third embodiment, the first input e1 of the current comparator CC is connected to the first input/output node RBL and the second input e2 is connected to the second node BLB to compare the current flowing through the pillar tunnel junction MTJ with the current through the second selector S2. The operation and advantages described with respect to the first embodiment remain valid for the second embodiment.

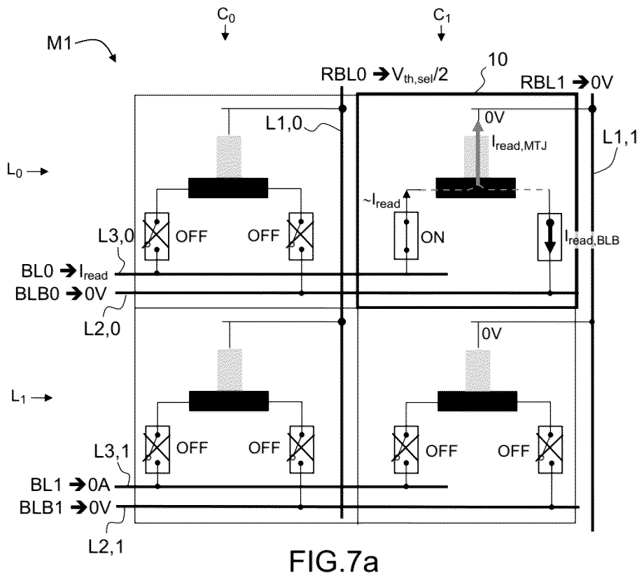

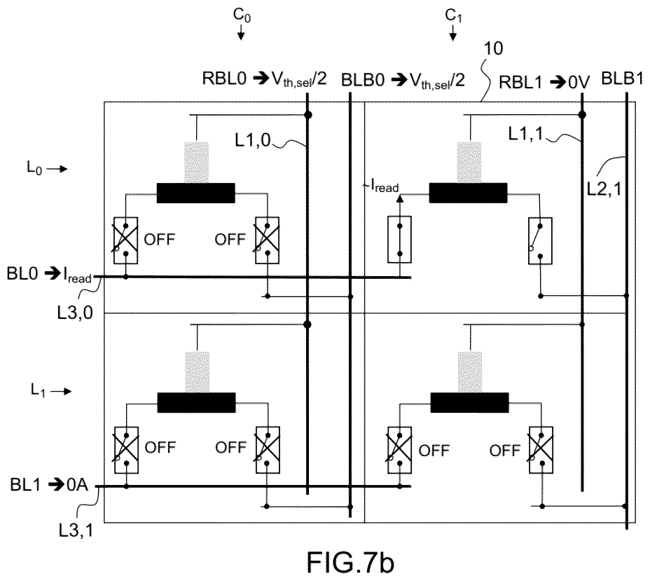

FIG. 7a illustrates an electrical schematic of a memory array M1 used in the memory circuit D1 according to a first embodiment of the invention.

The memory array M1 is formed by a plurality of memory cells CM according to the invention, which are arranged in rows Lᵢ and columns Cₖ, i=0 to N and k=0 to M. By way of illustration and non-limitingly, the array M1 is formed by two rows L₀, L₁ and two columns C₀ and C₁.

The first input/output nodes RBL of the memory cells CM belonging to the same column Cₖ of the memory array M1 are interconnected via a first conductive line L1,k intended to propagate the first control voltage VRBLₖ associated with said column Cₖ. The second input/output nodes BLB of the memory cells CM belonging to the same row Lᵢ of the memory array M1 are interconnected via a second conductive line L2,i intended to propagate the second control voltage VBLBᵢ associated with said row. The third input/output nodes BL of the memory cells 10 belonging to the same row of the memory array M1 are interconnected via a third conductive line L3,i intended to propagate the associated third control voltage VBLᵢ.

This array architecture is compatible with the read mode according to the invention described above. Table 1 illustrates the control voltages applied by control means to select and read a memory cell CM in the context of the array M1.

| | Selected cell | Cells not selected |
|---|---|---|
| I_{BL} | I_{read} | 0 A |
| V_{BLB} | 0 V | 0 V |
| V_{RBL} | 0 V | 0 < VRBL < Vₜₕ |

Advantageously, in respect of cells that are not selected, the control means CONT are configured to apply 0.2×Vₜₕ<VRBL<0.8×Vₜₕ to avoid accidental selection of non-targeted memory cells.

FIG. 7b illustrates an electrical schematic of a memory array M2 used in the memory circuit D1 according to a second embodiment of the invention.

The memory array M2 is formed by a plurality of memory cells CM according to the invention, which are arranged in rows Lᵢ and columns Cₖ, i=0 to N and k=0 to M. By way of illustration and non-limitingly, the array M1 is formed by two rows L₀, L₁ and two columns C₀ and C₁.

The first input/output nodes RBL of the memory cells CM belonging to the same column Cₖ of the memory array M2 are interconnected via a first conductive line L1,k intended to propagate the first control voltage VRBLₖ associated with said column Cₖ. The second input/output nodes BLB of the memory cells CM belonging to the same column Cₖ of the memory array M2 are interconnected via a second conductive line L2,k intended to propagate the second control voltage VBLBₖ associated with said column. The third input/output nodes BL of the memory cells 10 belonging to the same row of the memory array M1 are interconnected via a third conductive line L3,i intended to propagate the associated third control voltage VBLᵢ.

This array architecture is compatible with the read mode according to the invention described above. Table 2 illustrates the control voltages applied to select and read a memory cell CM in the context of the array M2.

| | Selected cell | Cells not selected |
|---|---|---|
| I_{BL} | I_{read} | 0 A |
| V_{BLB} | 0 V | 0 < VBLB < Vₜₕ |
| V_{RBL} | 0 V | 0 < VRBL < Vₜₕ |

Advantageously, in respect of cells that are not selected, the control means CONT are configured to apply 0.2×Vₜₕ<VRBL<0.8×Vₜₕ and 0.2×Vₜₕ<VBLB<0.8×Vₜₕ to avoid accidental selection of non-targeted memory cells.

1. A memory circuit (D1) comprising a read circuit (CL) and a memory array (M1, M2) comprising at least one magnetoresistive memory cell (CM), the memory cell (CM) comprising:
a pillar (MTJ) forming a magnetic tunnel junction (MTJ) having an upper end and a lower end, said upper end forming a first node (RBL) intended to receive a first control voltage (VRBL);
a write track (SOT) made of a material exhibiting the spin Hall effect or a material exhibiting the orbital Hall effect, the pillar (MTJ) being placed, on said write track (SOT), on the side of its lower end with a view to configuring the resistance (R_{MTJ}) of the magnetic tunnel junction (MTJ) between a high resistive state R_{AP} and a low resistive state R_{P};
a second node (BLB) intended to receive a second control voltage (VBLB) and a third node (BL);
a first selector (S1) mounted between the third node (BL) and a first end of the write track (SOT) and a second selector (S2) mounted between the second node (BLB) and a second end of the write track (SOT) opposite the first end;
each selector (S1, S2) being configured to switch from an off state to an on state when the amplitude of the voltage across the terminals of said selector is higher than a predetermined threshold voltage Vₜₕ;
the read circuit (CL) comprising:
a current source (GC) connected to the third node (BL) and configured to inject a read current (I_{read}) through the first selector (S1);
a detect circuit (CD) configured to detect when the second selector (S2) switches from an off state to an on state in response to injection of the read current (I_{read}) by detecting the resistive state of the magnetic tunnel junction.

2. The memory circuit (D1) according to claim 1, wherein the detect circuit (CD) comprises a current comparator (CC) having a first input (e1) connected to the second node (BLB) and having a second input (e2) receiving a reference current (I_{ref}) lower than the read current (I_{read}) and higher than the leakage current (I_{leak,s2}) of the second selector (S2) when it is in an off state.

3. The memory circuit (D1) according to claim 1, wherein the detect circuit (CD) comprises a current comparator (CC) having a first input (e1) connected to the first node (RBL) and having a second input (e2) receiving a reference current (I_{ref}) lower than the read current (I_{read}) and higher than the leakage current (I_{leak,MTJ}) of the magnetic tunnel junction (MTJ) when it is in a high resistive state R_{AP}.

4. The memory circuit (D1) according to claim 1, wherein the detect circuit (CD) comprises a current comparator (CC) having a first input (e1) connected to the first node (RBL) and having a second input (e2) connected to the second node (BLB).

5. The memory circuit (D1) according to claim 1, wherein the current source (GC) is configured to inject a read current (I_{read}) having an amplitude higher than
$$\frac{{R}_{AP} + {R}_{OFF , S 2}}{{R}_{AP} {R}_{OFF , S 2}} {V}_{th}$$
and lower than
$$\frac{{R}_{P} + {R}_{OFF , S 2}}{{R}_{P} {R}_{OFF , S 2}} {V}_{th} ,$$
R_{OFF,S2} being the resistance of the second selector (S2) when it is in the off state.

6. The memory circuit (D1) according to claim 1, wherein the current source (GC) is configured to inject a read current (I_{read}) having an amplitude higher than
$$\frac{{V}_{th}}{{R}_{OFF , S 1}} ,$$
R_{OFF,S1} being the resistance of the first selector (S1) when it is in the off state.

7. The memory circuit (D1) according to claim 1, wherein the current source (GC) is configured to inject a read current (I_{read}) having an amplitude higher than
$$\frac{{V}_{th}}{{R}_{OFF , S 1}} \frac{{R}_{AP} + {R}_{OFF , S 2}}{{R}_{AP} {R}_{OFF , S 2}} {V}_{th}$$
is reached, R_{OFF,S1} being the resistance of the first selector (S1) when it is in the off state, R_{OFF,S2} being the resistance of the second selector (S2) when it is in the off state.

8. The memory circuit (D1) according to claim 1, wherein:
the first nodes (RBL) of the memory cells (CM) belonging to the same column of the memory array (M1) are interconnected via a first conductive line (L_{1,0}; L_{1,1}) intended to propagate the associated first control voltage (VRBL₀, VRBL₁);
the second nodes (BLB) of the memory cells (CM) belonging to the same row of the memory array (M1) are interconnected via a second conductive line (L_{2,0}; L_{2,1}) intended to propagate the associated second control voltage (VBLB₀, VBLB₁);
the third nodes (BL) of the memory cells (CM) belonging to the same row of the memory array (M1) are interconnected via a third conductive line (L_{3,0}; L_{3,1}) intended to propagate the read current (I_{read}).

9. The memory circuit (D1) according to claim 8, further comprising control means (CONT) configured to read a selected memory cell (CM) of the array (M1) by connecting its first node (RBL) and its second node (BLB) to electrical ground (GND), and by applying, to non-selected memory cells, a first non-zero control voltage (VRBL) lower than the predetermined threshold voltage Vₜₕ.

10. The memory circuit (D1) according to claim 1, wherein:
the first nodes (RBL) of the memory cells (CM) belonging to the same column of the memory array (M2) are interconnected via a first conductive line (L_{1,0}; L_{1,1}) intended to propagate the associated first control voltage (VRBL₀, VRBL₁);
the second nodes (BLB) of the memory cells (CM) belonging to the same column of the memory array (M1) are interconnected via a second conductive line (L_{2,0}; L_{2,1}) intended to propagate the associated second control voltage (VBLB₀, VBLB₁);
the third nodes (BL) of the memory cells (CM) belonging to the same row of the memory array (M1) are interconnected via a third conductive line (L_{3,0}; L_{3,1}) intended to propagate the read current (I_{read}).

11. The memory circuit (D1) according to claim 10, further comprising control means (CONT) configured to read a selected memory cell (CM) of the array (M2) by connecting its first node (RBL) and its second node (BLB) to electrical ground, and by applying, to non-selected memory cells, a first non-zero control voltage (VRBL) lower than the predetermined threshold voltage Vₜₕ and a second non-zero control voltage (VRBL) lower than the predetermined threshold voltage Vₜₕ.
